(19) United States
(12) Patent Application Publication
(10) Pub. No.: US 2026/0119726 A1
(43) Pub. Date: Apr. 30, 2026

(54) ICE MOLD

(71) Applicant: Steven Ross, JR., Knoxville, TN (US)

(72) Inventor: Steven Ross, JR., Knoxville, TN (US)

(73) Assignee: Team Ice LLC, Knoxville, TN (US)

(21) Appl. No.: 18/927,995

(22) Filed: Oct. 26, 2024

(51) Int. Cl. G06F 30/10; B29C 59/02; B29L 31/00; F25C 1/243

(52) U.S. Cl. CPC G06F 30/10; B29C 59/022; B29L 2031/757; F25C 1/243

(57) ABSTRACT

A system for developing molds for creating ice cubes bearing recognizable symbols is provided. The system comprises a computer and an application stored in the computer that when executed receives a description of an object to be spatially imitated by a frozen structure. The system also creates, using at least the description, a design of a mold for production of the frozen structure, the design enabling at least a three-dimensional rendering of the object. The system manufactures, based on the design, a three-dimensional mold comprising a bottom component with a concave cuplike shape, with flat base and vertical sides, and with the rendering impressed into an upward facing interior surface of the base. The mold comprises a top component functioning as a lid to fit over the bottom component in a sealing manner, the top component with the rendering similarly impressed into a downward facing surface of the top component.

### CROSS REFERENCE TO RELATED APPLICATIONS

The present disclosure is related to U.S. Provisional Patent No. 63/539,959 filed Sep. 22, 2023, the contents of which are incorporated herein in their entirety.

### FIELD OF THE DISCLOSURE

The present disclosure is in the field of home furnishings. More particularly, the present disclosure provides systems and methods of making and using an ice cube mold that bears a raised, three-dimensional image wherein the image may be a trademarked logo of a university, firm, or other entity.

### BACKGROUND

Alumni and supporters of universities enjoy displaying and using goods that display the trademarked logos and symbols of their institutions. Whether on hats, garments, household items, bumper stickers, flags, banners, or other objects, alumni and supporters with loyalty to their institutions enjoy displaying such items to exhibit their pride and exhort others to do so as well. The same may be true for supporters of other organizations or causes.

### BRIEF DESCRIPTION OF THE FIGURES

FIG. 1 is an image of an ice mold according to an embodiment of the present disclosure.

FIG. 2a is an image of an ice mold according to an embodiment of the present disclosure.

FIG. 2b is an image of an ice mold according to an embodiment of the present disclosure.

FIG. 2c is an image of an ice mold according to an embodiment of the present disclosure.

FIG. 3 is an image of an ice mold according to an embodiment of the present disclosure.

FIG. 4a is an image of an ice mold according to an embodiment of the present disclosure.

FIG. 4b is an image of an ice mold according to an embodiment of the present disclosure.

FIG. 4c is an image of an ice mold according to an embodiment of the present disclosure.

### DETAILED DESCRIPTION

Systems and methods described herein provide an ice cube mold in two components wherein recessed imprints are made in the interior surfaces of each component of the mold such that ice cubes made with the mold have raised images caused by the imprints. The images may be of many types of objects including logos of universities such that alumni, students, and other supporters may enjoy beverages with ice cubes bearing their school's logo or other popular symbols. Logos or symbols associated with other types of organizations may also be used.

A two-piece mold comprising a body and a lid are provided. The body is a cup-like object made of hard plastic with an imprint of the logo or symbol of interest impressed into the upward-facing inner bottom surface or floor of the body. This structure allows the ice cube when provided to bear the logo in a raised fashion.

Vertical sides of the body may rise in the same shape as the imprinted logo. The vertical sides may alternatively be boxlike or they may be shaped in another manner. The lid may be made of food-grade silicone and fits atop the body. An imprint of the logo may be impressed into the downward facing inner surface or underside of the lid.

In an embodiment, the body is filled with water to the top or lip of the body and the lid is placed firmly over the body. The combined body and lid are then frozen. When the lid is removed after freezing and the frozen cube is removed from the body, the result is an ice cube with the logo on opposite sides or ends of the cube, where the upward-facing bottom surface of the body and the downward-facing underside of the lid had faced. The logo appears in a raised manner from surfaces of the newly produced ice cube. If the vertical sides rise in the same shape as the logo, the entire cube may be in the shape of the logo.

The system may be manufactured in a variety of manners. Computer programs can receive dimensions of the raised three-dimensional logo and provide instructions to machinery to create a stamp. The stamp may be made of such material that it can be used during manufacturing of the hard plastic bottom portion or body and place the impression of the logo into the bottom at the appropriate time during manufacturing. The stamp may also be used to place an impression of the logo into the bottom-facing or underside surface of the lid.

The lid may not be entirely flat. The lid has sides extending downward, similar to the vertical sides of the body. The sides of the lid extend downward and slide alongside the upward vertical sides from the base or body. The sides extending downward from the lid are shaped exactly or almost exactly in the shape of the sides extending upward from the body such that the two sets of sides promote sealing the liquid inside the combined components when the lid is placed atop the body.

The lid also has a small hole passing entirely through it vertically to allow air into or out of the chamber created by the combined body and lid. As the contained liquid freezes or thaws, the liquid may expand or contract and air may need to be expelled or drawn in, respectively. The hole facilitates these processes.

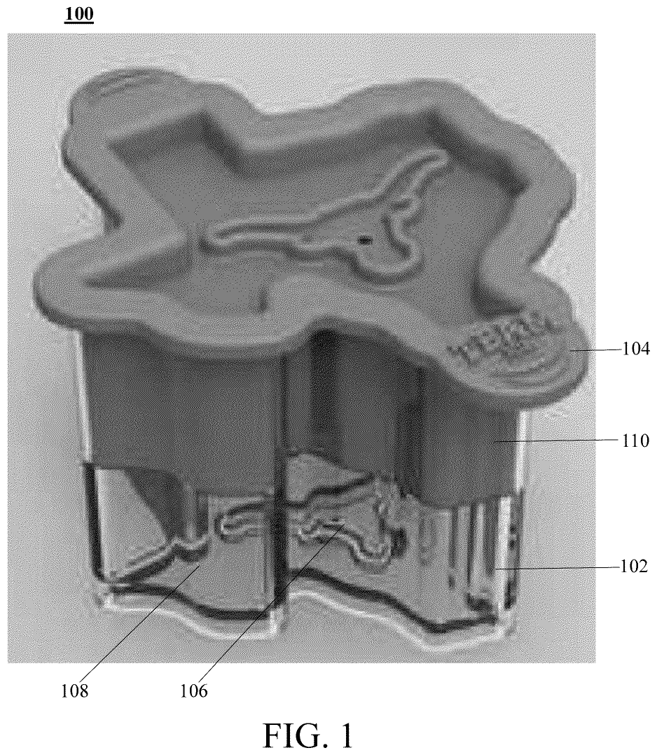

Turning to the figures, FIG. 1 is an image of an ice mold according to an embodiment of the present disclosure. A system 100 is provided comprising a bottom component 102, a top component 104, a bottom imprint 106, first sides 108, and second sides 110. The bottom component 102 may be made of hard plastic and has a flat internal base surface or floor. The bottom imprint 106 is visible, the imprint having been impressed into the base surface using a stamp, as part of an injection molding process that manufactured the entire bottom component 102, or via other method. The imprint 106 is a concave impression in the shape of a trademarked or non-trademarked logo or symbol.

The first sides 108 rise upward from the base or bottom component 102. The second sides 110 extend downward from the underside of the top component 104. As is visible in FIG. 1, the second sides 110 fit closely against the first sides 108 as the tip component 104 is pressed down onto the bottom component 102 after water is placed into the bottom component. The close fit of the first sides 108 against the top sides 110 helps seal the components 102, 104 together and prevent the water from escaping once sealed together.

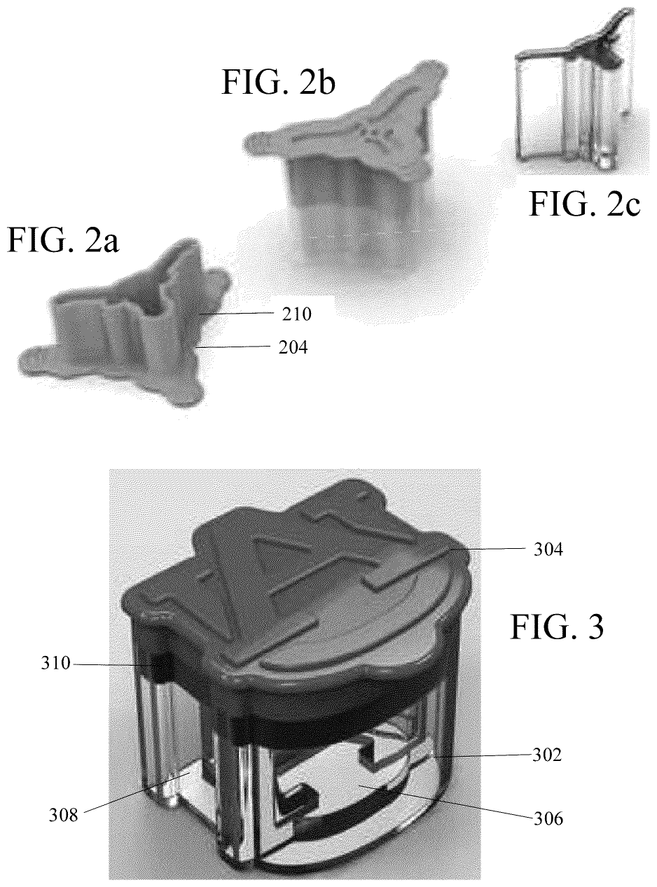

FIG. 2a-c are other images of the ice mold according to an embodiment of the present disclosure. Components in FIG. 2 through FIG. 4 are indexed to components of FIG. 1 and the system 100. A system 200 is provided herein and depicted in FIG. 2a-c. FIG. 2 illustrates the top component 204 turned over with the second sides 110 fully visible. It should be noted that the imprint in the underside of the top component 104, 204 is not visible in any of the drawings provided here but is definitively present. FIG. 2b shows the top component 204 in its normal position and FIG. 2c depicts an ice cube made with the system 200 or system 100.

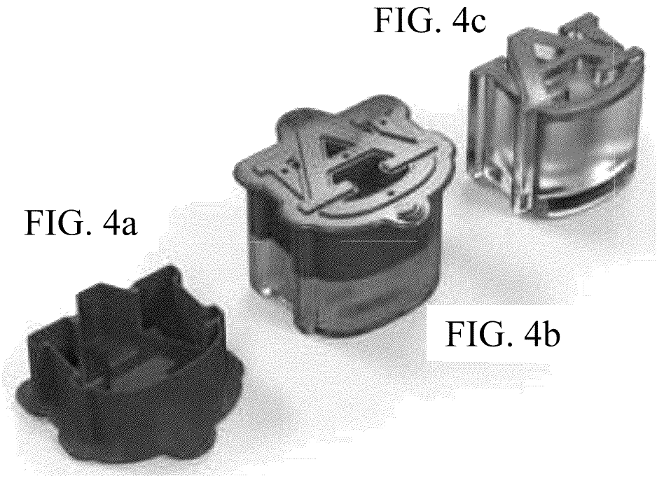

FIG. 3 is another image of the ice mold depicting components of a system 300 including a bottom component 302, a top component 304, imprint 306, first sides 308. FIG. 4a-c are similar to FIG. 2a-c. FIG. 4c is a view of an ice cube produced by the system 300.

In an alternative structure, a one-piece mold may be created by forming a single amount of silicone into a cube-like structure without a top. Water may be filled into the structure and frozen. The ice cube, when formed, may be forced out of the structure by manually pushing on the bottom surface of the structure. In this embodiment and the others described above, it may be necessary to briefly run water over the components to loosen the formed ice cube from the components.

In an embodiment, a system for developing molds for creating ice cubes bearing recognizable symbols is provided. The system comprises a computer and an application stored in the computer that when executed receives a description of an object to be spatially imitated by a frozen structure. The system also creates, using at least the description, a design of a mold for production of the frozen structure, the design enabling at least a three-dimensional rendering of the object. The system also manufactures, based on the design, a three-dimensional mold comprising a bottom component with a concave cuplike shape, with a flat base and vertical sides, and with the rendering impressed into an upward facing interior surface of the base. The three-dimensional mold also comprises a top component functioning as a lid to fit over the bottom component in a sealing manner, the top component with the rendering similarly impressed into a downward facing surface of the top component.

Liquid is placed inside the bottom component before the top component is placed atop the base component. The top component fits over the bottom component in a sealed manner such that liquid placed inside the joined components remains in place when the joined components are placed in a freezer for the purpose of freezing the liquid and producing an ice cube.

The top and bottom components have straight sides protruding downward and upward, respectively, from subcomponents hosting the renderings. The object is a trademarked logo.

After the liquid is frozen, the components are removed, and the frozen liquid is in a form of an ice cube with the renderings comprising raised, three-dimensional impressions of the trademarked logo. The bottom component is made of plastic and the top component is made of silicone.

In another embodiment, a method for enabling production of ice cubes bearing customized symbols is provided. The method comprises a computer receiving a request for an ice cube mold customized to bear a surface resembling a symbol. The method also comprises the computer receiving a three-dimensional prototype of the symbol. The method also comprises the computer directing scanning of at least the prototype and production of a stamp based on the symbol, the stamp fit for use in manufacturing. The method also comprises the computer stamping a first imprint, using the stamp, of the symbol into an upward facing interior surface of a cuplike lower half of a mold. The method also comprises the computer similarly creating a second imprint, using the stamp, into a downward facing interior surface of an upper half of the mold.

The lower half contains liquid subject to freezing and creation of an ice cube and the upper half is a lid that fits atop the lower half and seals the liquid inside the lower half during freezing. The method also comprises the computer creating the lower half from plastic and creating the upper half from silicone.

The symbol is a trademarked logo. The method also comprises the computer creating the stamp based on the three-dimensional prototype.

The method also comprises the computer controlling manufacturing equipment to manufacture the mold. The ice cube when produced upon freezing and removal from the lower half after removal of the upper half, bears the symbol on two of its six surfaces, the symbol recognizable as the trademarked logo.

In yet another embodiment, a method is provided for creating a mold to produce ice cubes with raised three-dimensional symbols. The method comprises receiving a quantity of silicone suitable for use in manufacturing processes and durable for exposure to freezing temperatures. The method also comprises creating a stamp with a three-dimensional raised portion, the stamp for use in embossing impressions into the silicone during the manufacturing processes. The method also comprises manufacturing a cube-shaped hollow mold with the silicone, the object with four vertical side panels, one horizontal bottom panel, and an open top. The method also comprises creating, during the manufacturing process and using the stamp, a three-dimensional impression into an internal upward facing surface of the horizontal bottom panel.

The mold, upon completion of the manufacturing process, is filled with liquid and frozen. The mold, after freezing, produces a cube with one side bearing the raised three-dimensional impression. The produced cube is manually removed from the mold via exertion of force against a bottom surface of the mold.

The impression resembles one of a logo and a trademarked insignia. The mold is a single continuous object.

What is claimed is:

1. A system for developing molds for creating ice cubes bearing recognizable symbols, comprising:
a computer; and
an application stored in the computer that when executed:
receives a description of an object to be spatially imitated by a frozen structure,
creates, using at least the description, a design of a mold for production of the frozen structure, the design enabling at least a three-dimensional rendering of the object,
manufactures, based on the design, a three-dimensional mold comprising:
a bottom component with a concave cuplike shape, with a flat base and vertical sides, and with the rendering impressed into an upward facing interior surface of the base,
a top component functioning as a lid to fit over the bottom component in a sealing manner, the top component with the rendering similarly impressed into a downward facing surface of the top component.

2. The system of claim 1, wherein liquid is placed inside the bottom component before the top component is placed atop the base component.

3. The system of claim 1, wherein the top component fits over the bottom component in a sealed manner such that liquid placed inside the joined components remains in place when the joined components are placed in a freezer for the purpose of freezing the liquid and producing an ice cube.

4. The system of claim 1, wherein the top and bottom components have straight sides protruding downward and upward, respectively, from subcomponents hosting the renderings.

5. The system of claim 1, wherein the object is a trademarked logo.

6. The system of claim 1, wherein after the liquid is frozen, the components are removed, and the frozen liquid is in a form of an ice cube with the renderings comprising raised, three-dimensional impressions of the trademarked logo.

7. The system of claim 1, wherein the bottom component is made of plastic and the top component is made of silicone.

8. A method for enabling production of ice cubes bearing customized symbols, comprising:
a computer receiving a request for an ice cube mold customized to bear a surface resembling a symbol;
the computer receiving a three-dimensional prototype of the symbol;
the computer directing scanning and production of a stamp based on the symbol, the stamp fit for use in manufacturing;
the computer stamping a first imprint, using the stamp, of the symbol into an upward facing interior surface of a cuplike lower half of a mold; and
the computer similarly creating a second imprint, using the stamp, into a downward facing interior surface of an upper half of the mold.

9. The method of claim 8, wherein the lower half contains liquid subject to freezing and creation of an ice cube and the upper half is a lid that fits atop the lower half and seals the liquid inside the lower half during freezing.

10. The method of claim 8, further comprising the computer creating the lower half from plastic and creating the upper half from silicone.

11. The method of claim 8, wherein the symbol is a trademarked logo.

12. The method of claim 8, further comprising the computer creating the stamp based on the three-dimensional prototype.

13. The method of claim 8, further comprising the computer controlling manufacturing equipment to manufacture the mold.

14. The method of claim 8, wherein the ice cube when produced upon freezing and removal from the lower half after removal of the upper half, bears the symbol on two of its six surfaces, the symbol recognizable as the trademarked logo.

15. A method of creating a mold to produce ice cubes with raised three-dimensional symbols, comprising:
receiving a quantity of silicone suitable for use in manufacturing processes and durable for exposure to freezing temperatures;
creating a stamp with a three-dimensional raised portion, the stamp for use in embossing impressions into the silicone during the manufacturing processes;
manufacturing a cube-shaped hollow mold with the silicone, the object with four vertical side panels, one horizontal bottom panel, and an open top; and
creating, during the manufacturing process and using the stamp, a three-dimensional impression into an internal upward facing surface of the horizontal bottom panel.

16. The method of claim 15, wherein the mold, upon completion of the manufacturing process, is filled with liquid and frozen.

17. The method of claim 15, wherein the mold, after freezing, produces a cube with one side bearing the raised three-dimensional impression.

18. The method of claim 17, wherein the produced cube is manually removed from the mold via exertion of force against a bottom surface of the mold.

19. The method of claim 15, wherein the impression resembles one of a logo and a trademarked insignia.

20. The method of claim 15, wherein the mold is a single continuous object.
